(19) United States
(12) Patent Application Publication
(10) Pub. No.: US 2023/0035627 A1
(43) Pub. Date: Feb. 2, 2023

(54) SPLIT DIE INTEGRATED CIRCUIT (IC) PACKAGES EMPLOYING DIE-TO-DIE (D2D) CONNECTIONS IN DIE-SUBSTRATE STANDOFF CAVITY, AND RELATED FABRICATION METHODS

(71) Applicant: QUALCOMM Incorporated, San Diego, CA (US)

(72) Inventors: Aniket Patil, San Diego, CA (US); Brigham Navaja, San Diego, CA (US); Hong Bok We, San Diego, CA (US)

(21) Appl. No.: 17/443,740

(22) Filed: Jul. 27, 2021

(51) Int. Cl. H01L 25/065; H01L 23/00; H01L 23/31; H01L 25/00

(52) U.S. Cl. CPC H01L 25/0655; H01L 24/16; H01L 24/24; H01L 23/3107; H01L 25/50; H01L 2224/16225; H01L 2224/24137

(57) ABSTRACT

Split die IC packages employing a D2D interconnect structure in a die-substrate standoff cavity (i.e., cavity) to provide D2D connections, and related fabrication methods. To facilitate D2D communications between multiple dies in the split die IC package, the package substrate also includes a D2D interconnect structure (e.g., interconnect bridge) that contains D2D interconnects (e.g., metal interconnects) coupled to the multiple dies to provide D2D signal routing between the multiple dies. The D2D interconnect structure is disposed in a cavity that is formed in a die standoff area between the dies and the package substrate as a result of the die interconnects being disposed between the dies and the package substrate standing off the dies from the package substrate. The D2D interconnect structure can be provided in the cavity in the IC package outside of the package substrate to reserve more area in the package substrate for other interconnections.

### BACKGROUND

### I. Field of the Disclosure

The field of the disclosure relates to integrated circuit (IC) packages, and more particularly to split semiconductor die IC packages.

### II. Background

Integrated circuits (ICs) are the cornerstone of electronic devices. ICs are packaged in an IC package, also called a “semiconductor package” or “chip package.” The IC package includes one or more semiconductor dies as an IC(s) that are mounted on and electrically coupled to a package substrate to provide physical support and an electrical interface to the semiconductor die(s). The package substrate includes one or more metallization layers that include electrical traces (e.g., metal lines) with vertical interconnect accesses (vias) coupling the electrical traces together between adjacent metallization layers to provide electrical interfaces between the semiconductor die(s). The semiconductor die(s) is mounted to and electrically interfaced to metal interconnects exposed in a top or outer layer of the package substrate to electrically couple the semiconductor die(s) to the electrical traces of the package substrate. The package substrate includes an external outer layer with metal interconnects to provide an external interface between the semiconductor die(s) in the IC package and external circuitry.

IC packages come in many varieties based on the intended application. A split semiconductor die IC package (“split die” IC package) is a package containing two (2) or more semiconductor dies that are conventionally disposed side-by-side to each other. The semiconductor dies are mounted on and electrically coupled to a package substrate to provide physical support and to provide an electrical interface to the semiconductor dies. It may be necessary according to the designed operation of the split die IC package to provide a signal interface between the split dies for die-to-die (D2D) communications. For example, each split die may include a D2D interface circuitry that provides a communication signal interface to internal circuitry and another die. In this regard, a split die IC package can include a D2D interconnect structure that includes D2D connections between each die's D2D interface circuitry together to provide a signal interface between the dies. Conventional split die IC packages employ a D2D interposer to provide the D2D interconnect structure. For example, this D2D interposer may be provided as a silicon interposer in a package substrate that acts like a signal interface bridge. As another example, the D2D interposer may be an embedded wafer level package (eWLP) that includes multiple redistribution layers (RDLs) as metallization layers to support D2D connections. However, in either case, providing the additional metallization layers to provide the D2D connections can increase the height of the package of the IC package in an undesirable manner.

### SUMMARY OF THE DISCLOSURE

Aspects disclosed herein include exemplary split die integrated circuit (IC) packages employing die-to-die (D2D) interconnect structures in a die-substrate standoff cavity (i.e., cavity) to provide D2D connections. Related fabrication methods are also disclosed. In exemplary aspects, the split die IC package includes at least two semiconductor dies (“dies”) coupled to a package substrate. The package substrate includes one or more metallization layers each with metal interconnects (e.g., metal lines or traces) that can provide signal routing between the dies and external interconnects (e.g., solder bumps). The split die IC package includes a plurality of die interconnects (e.g., die bumps with solder joints) between the dies and the package substrate that electrically couple the dies to the package substrate for signal routing. In exemplary aspects, to facilitate D2D communications between multiple dies in the split die IC package, the package substrate also includes a D2D interconnect structure (e.g., an interconnect bridge) that contains D2D interconnects (e.g., metal interconnects) coupled to the multiple dies to provide D2D signal routing between the multiple dies. The D2D interconnect structure is disposed in a cavity that is formed in a die standoff area between the dies and the package substrate as a result of the die interconnects being disposed between the dies and the package substrate standing off the dies from the package substrate. In this manner, the D2D interconnect structure can be provided in the cavity in the IC package outside of the package substrate to reserve more area in the package substrate for other interconnections, such as between the dies and the external interconnects. Providing a D2D interconnect structure outside of the package substrate can also reduce the overall height of the split die IC package, because area of the package substrate that would otherwise be consumed by metal interconnects for D2D connections can be used for other signal routing and/or other devices (e.g., passive devices). Also, by providing the D2D interconnect structure in a cavity, the D2D interconnects can be located closer to the dies than would be the case if provided in the package substrate, and thus shorter in length thereby reducing their resistance for increased D2D signaling speed.

In certain exemplary aspects, the D2D interconnect structure is formed by one or more redistributed layers (RDLs) that are built up on a die module adjacent to active sides of the dies. The RDLs are built up on the die module and coupled to die interconnects of the dies that are used for D2D communications. The RDLs can also be built up on the die module in a confined area that will form the die standoff area without having to form RDLs that span the entire horizontal area between the die module and the package substrate, which would increase the height of the split die IC package. Providing the D2D interconnect structure as a RDL(s) can facilitate thinner metallization layers with metal interconnects of smaller patterned sizes (i.e., line (L)/spacing (S)(L/S)) for the D2D interconnects than may be able to be fabricated in a conventional laminate substrate. Thus, providing the D2D interconnects in RDLs can facilitate higher density D2D interconnects in the split die IC package. RDLs also do not require solder joints to be used to connect the D2D interconnect structure to die interconnects of the dies. This may be particularly useful for dies with high density die interconnects coupled to the D2D interconnects to provide D2D communications.

In other examples, the RDL layers of the D2D interconnect structure are formed on the die module as a reconstituted wafer forming a reconstituted die module. In this regard, the dies can be formed on a first wafer and then diced and re-positioned on a reconstituted wafer as part of a fan-out wafer-level packaging (FOWLP) process. The dies on the reconstituted wafer can be diced to provide the die module as a reconstituted die module. Providing the die module as a reconstituted die module can allow good die placement control so that the dies can be placed closer together to further reduce package size. Also, providing the die module as a reconstituted die module can provide a convenient process to build up the RDLs for the D2D interconnect on the reconstituted die module with the multiple dies present. In this manner, the RDLs can be coupled to die interconnects of the die modules as the RDLs are fabricated on the reconstituted die module. The die module with the built-on RDLs forming the D2D interconnect can then be coupled to the package substrate as part of fabricating the split die IC package.

Note that providing the D2D interconnect structure in the die standoff area outside of the package substrate of the split die IC package does not preclude metallization layers in the package substrate from also being used to provide D2D interconnections. Including a D2D interconnect structure in the die standoff area outside of the package substrate can reduce or minimize the need to provide D2D connections in the package substrate.

In this regard, in one exemplary aspect, an IC package is provided. The IC package comprises a package substrate, a first die, and a second die. The IC package also comprises a first plurality of die interconnects coupled to the package substrate and the first die creating a die standoff area between the first die and the package substrate. The IC package also comprises a second plurality of die interconnects disposed in the die standoff area and coupled to the package substrate and the second die. A cavity is formed in the die standoff area between the first plurality of die interconnects and the second plurality of die interconnects. The IC package also comprises a D2D interconnect structure disposed in the cavity. The D2D interconnect structure comprises a plurality of D2D interconnects coupled to the first die and the second die.

In another exemplary aspect, a method of fabricating an IC package is provided. The method comprises forming a die module comprising an active side, a first die comprising a first active side adjacent the active side, and a second die comprising a second active side adjacent to the active side, the second die horizontally adjacent to the first die. The method also comprises forming a D2D interconnect structure adjacent to the active side of the die module, the D2D interconnect structure comprising a plurality of D2D interconnects. The method also comprises forming a first plurality of die interconnects coupled the first active side of the first die. The method also comprises forming a second plurality of die interconnects coupled to the second active side of the second die forming a cavity between the first plurality of die interconnects and the second plurality of die interconnects, and the D2D interconnect structure disposed in the cavity. The method also comprises disposing the die module on a package substrate, comprising coupling the first plurality of die interconnects to the package substrate, and coupling the second plurality of die interconnects to the package substrate.

### BRIEF DESCRIPTION OF THE FIGURES

FIGS. 1A and 1B are respective top and cross-sectional sides views of a split semiconductor die (“die”) integrated circuit (IC) package that includes a die-to-die (D2D) connection interposer in a package substrate for providing D2D connections;

FIGS. 2A and 2B are respective top and cross-sectional sides views of an exemplary split die IC package employing a D2D interconnect structure in a die-substrate standoff cavity (i.e., cavity) to provide D2D connections;

FIG. 3 is another side view of the split die IC package in FIG. 2B illustrating more detail of the D2D interconnect structure in a cavity providing D2D connections;

FIG. 4 is a flowchart illustrating an exemplary process for fabricating a split die IC package employing a D2D interconnect structure in a cavity to provide D2D connections, including, but not limited to, the exemplary split die IC package in FIGS. 2A-3;

FIGS. 5A-5C are a flowchart illustrating another exemplary process for fabricating a split die IC package employing a D2D interconnect structure in a cavity to provide D2D connections including, but not limited to, the exemplary split die IC package in FIGS. 2A-3;

FIGS. 6A-6H illustrate exemplary fabrication stages during fabrication of a split die IC package employing a D2D interconnect structure in a cavity to provide D2D connections, including, but not limited to, the exemplary split die IC package in FIGS. 2A-3 and according to the exemplary fabrication process in FIGS. 5A-5C;

FIG. 7 is a block diagram of an exemplary processor-based system that includes components that can be packaged in a split die IC package(s) employing a D2D interconnect structure in a cavity to provide D2D connections including, but not limited to, the exemplary split die IC package in FIGS. 2A-3, and according to the exemplary fabrication processes in FIGS. 4-6H; and

FIG. 8 is a block diagram of an exemplary wireless communications device that includes radio frequency (RF) components that can be packaged in a split die IC package(s) employing a D2D interconnect structure in a cavity to provide D2D connections including, but not limited to, the exemplary split die IC package in FIGS. 2A-3, and according to the exemplary fabrication processes in FIGS. 4-6H.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include exemplary split-die integrated circuit (IC) packages employing die-to-die (D2D) interconnect structures in a die-substrate standoff cavity (i.e., cavity) to provide D2D connections. Related fabrication methods are also disclosed. In exemplary aspects, the split die IC package includes at least two semiconductor dies (“dies”) coupled to a package substrate. The package substrate includes one or more metallization layers each with metal interconnect that can provide signal routing between the dies and external interconnects (e.g., solder bumps). The split die IC package includes a plurality of die interconnects (e.g., die bumps with solder joints) between the dies and the package substrate that electrically couple the dies to the package substrate for signal routing. In exemplary aspects, to facilitate D2D communications between multiple dies in the split die IC package, the package substrate also includes a D2D interconnect structure (e.g., an interconnect bridge) that contains D2D interconnects (e.g., metal lines) coupled to the multiple dies to provide D2D signal routing between the multiple dies. The D2D interconnect structure is disposed in a cavity that is formed in a die standoff area between the dies and the package substrate as a result of the die interconnects being disposed between the dies and the package substrate standing off the dies from the package substrate. In this manner, the D2D interconnect structure can be provided in the cavity in the IC package outside of the package substrate to reserve more area in the package substrate for other interconnections, such as between the dies and the external interconnects. Providing a D2D interconnect structure outside of the package substrate can also reduce the overall height of the split die IC package, because area of the package substrate that would otherwise be consumed by metal interconnects for D2D connections can be used for other signal routing and/or other devices (e.g., passive devices). Also, by providing the D2D interconnect structure in a cavity, the D2D interconnects can be located closer to the dies than would be the case if provided in the package substrate, and thus shorter in length thereby reducing their resistance for increased D2D signaling speed.

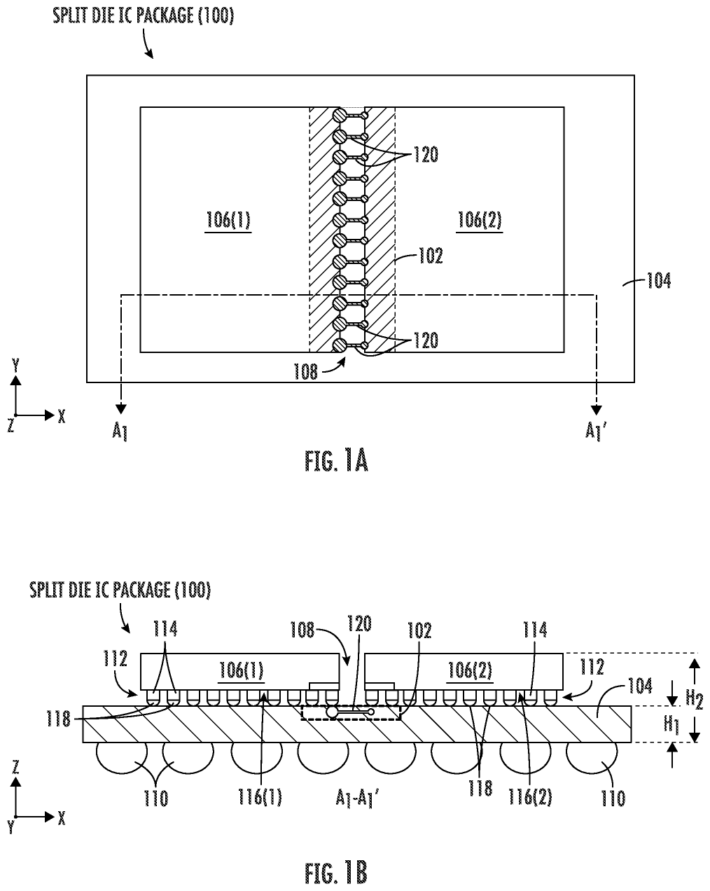

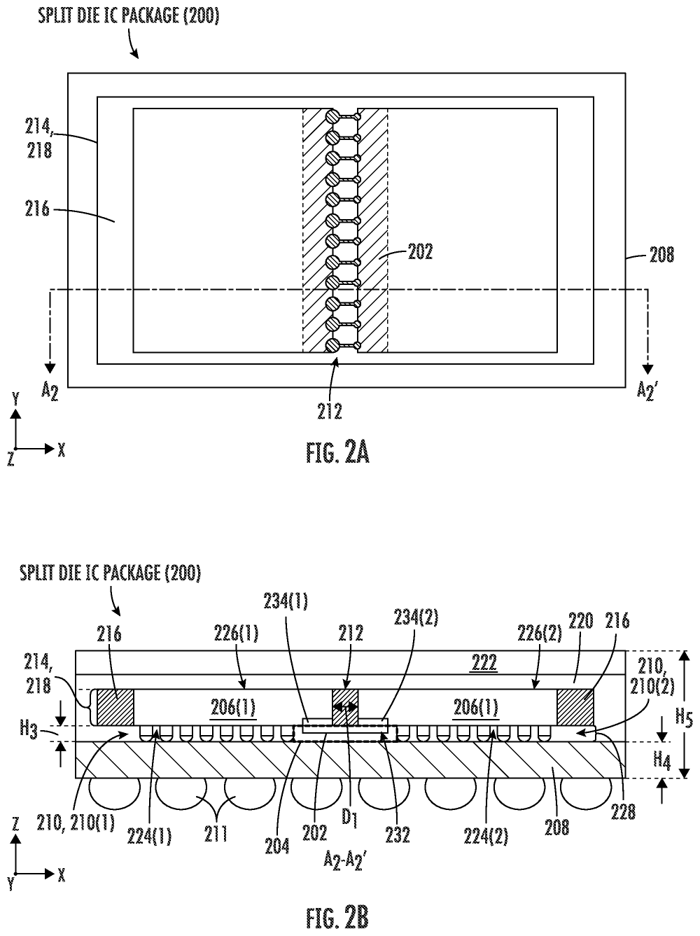

Before discussing examples of split-die IC packages employing a D2D interconnect structure in a cavity to provide D2D connections between multiple dies in the package starting at FIG. 2A, a split die IC package that does not include a D2D interconnect structure in a cavity is first described with regard to FIGS. 1A and 1B below.

In this regard, FIGS. 1A and 1B are respective top and cross-sectional sides views of a split semiconductor die (“die”) IC package 100 that includes a D2D interposer 102 in a package substrate 104 for providing D2D connections. The split die IC package 100 in FIG. 1B is shown as a cross-section along the A₁-A₁′ line in FIG. 1A. With reference to FIGS. 1A and 1B, the split die IC package 100 includes at least two semiconductor dies (“dies”) 106(1), 106(2) coupled to the package substrate 104. The dies 106(1), 106(2) are disposed horizontally adjacent to each other in the X-axis direction in this example with a die separation area 108 formed between the dies 106(1), 106(2). The package substrate 104 includes one or more metallization layers each with metal interconnects (e.g., metal lines or traces) that can provide signal routing between the dies 106(1), 106(2) and external interconnects 110 (e.g., solder balls). As shown in FIG. 1B, the split die IC package 100 includes a plurality of die interconnects 112 (e.g., die bumps with solder joints) between the dies 106(1), 106(2) and the package substrate 104 that electrically couple the dies 106(1), 106(2) to the package substrate 104 for signal routing. The die interconnects 112 include metal pillars 114 in this example that are coupled to die pads (not shown) on active sides 116(1), 116(2) of the respective dies 106(1), 106(2). The metal pillars 114 are coupled to the package substrate 104 with solder joints 118 formed on the metal pillars 114 and coupled to the package substrate 104.

To facilitate D2D communications between multiple dies 106(1), 106(2) in the split die IC package 100 in FIGS. 1A and 1B, the package substrate 104 also includes the D2D interposer 102. The D2D interposer 102 is disposed in the package substrate 104 below the die separation area 108 in this example. The D2D interposer 102 contains D2D interconnects 120 (e.g., metal lines) coupled to certain die interconnects 112 coupled to the respective dies 106(1), 106(2) that are dedicated for D2D signal routing between the dies 106(1), 106(2) for D2D communications. This D2D signal routing can be communications signals and coupling of common power rails, as examples. The D2D interposer 102 is conventionally located in upper metallization layers of the package substrate 104 to reduce the length of the D2D interconnects 120 to reduce resistance and improve signaling speed.

The inclusion of the D2D interposer 102 in the package substrate 104 consumes space in a metallization layer of the package substrate 104. This can contribute to an increased height of the package substrate H₁ in the Z-axis direction and thus the overall height of the split die IC package H₂ in the Z-axis direction, as shown in FIG. 1B. Also, including the D2D interconnects 120 in the package substrate 104 may be located close to other metal interconnects in the package substrate 104, such as power rails, that can create signal interference. The D2D communication signals carried over the D2D interconnects 120 may be particularly sensitive to interference as these signals may be higher-speed signals as part of a D2D bus interface between the dies 106(1), 106(2). Also, the location of the D2D interposer 102 being below and adjacent to the die separation area 108 can impact routing space in the package substrate 104. Other metal interconnects in the package substrate 104 that route signals other than D2D communications signals are isolated from the D2D interposer 102 and thus have to be routed in other areas outside the area of the D2D interposer 102. This can impact routing options and capabilities in the package substrate 104. For example, the D2D interposer 102 can interfere with routing paths for a power distribution network in the package substrate 104 creating longer power distribution paths. This can contribute to increased voltage drop in the power distribution network in the package substrate 104. Further, as the number and/or density of D2D interconnects 120 increases, the more likely the D2D interposer 102 will be disposed in additional metallization layers of the package substrate 104 thus further consuming area that could be used for other signal routing. Or alternatively, additional D2D interconnects from one die 106(1), 106(2) may have to be routed through the package substrate 104 to the external interconnects 110 and back to the other die 106(2), 106(1) to avoid the D2D interposer 102 consuming additional space in the package substrate 104.

FIGS. 2A and 2B are respective top and cross-sectional sides views of another exemplary split die IC package 200 that employs an alternative D2D connection structure to the D2D interposer 102 in the split die IC package 100 in FIGS. 1A and 1B to be able to avoid consuming space in the package substrate for D2D connections. In this regard, and as discussed in more detail below, the split die IC package 200 in FIGS. 2A and 2B includes a D2D interconnect structure 202 to provide D2D connections that is disposed in a die-substrate standoff cavity (i.e., cavity) 204. The die-substrate standoff cavity 204 is an area formed in a die standoff area 228 between semiconductor dies (“dies”) 206(1), 206(2) and a package substrate 208 as a result of die interconnects 210 that couple the dies 206(1), 206(2) to the package substrate 208, being disposed between the dies 206(1), 206(2) and the package substrate 208. The die-substrate standoff cavity 204 does not include space inside the package substrate 208 or the dies 206(1), 206(2) in one example. The die interconnects 210 “stand off” the dies 206(1), 206(2) from the package substrate 208 by the respective height H₃ of the die interconnects 210 to form the die-substrate standoff cavity 204 disposed between the dies 206(1), 206(2) and the package substrate 208.

In this manner, as shown in FIG. 2B, the D2D interconnect structure 202 is provided in the die-substrate standoff cavity 204 in the split die IC package 200 outside of the package substrate 208. This can reserve more area in the package substrate 208 for other interconnections, such as between the dies 206(1), 206(2) and external interconnects 211 (e.g., solder balls). Providing the D2D interconnect structure 202 outside of the package substrate 208 can also reduce the height H₄ of the package substrate 208 over what the height of the package substrate 208 would otherwise be if the D2D interconnect structure 202 were included in the package substrate 208. A reduced height H₄ of the package substrate 208 reduces the overall height H₅ of the split die IC package 200, because the area of the package substrate 208 that would otherwise be consumed by interconnects (e.g., metal lines, metal traces, vertical interconnect accesses (vias), pads) for D2D connections can be used for other signal routing and/or other devices (e.g., passive devices). Also, by providing the D2D interconnect structure 202 in the die-substrate standoff cavity 204 of the split die IC package 200, D2D interconnections in the D2D interconnect structure 202 can be located closer to the dies 206(1), 206(2) than would be the case if provided in the package substrate 208. This can reduce the length of the D2D interconnects thereby reducing their resistance for increased D2D signaling speed between the dies 206(1), 206(2).

With continuing reference to FIGS. 2A and 2B, the split die IC package 200 in FIG. 2B is shown as a cross-section along the A₂-A₂′ line in FIG. 2A. The dies 206(1), 206(2) are coupled to the package substrate 208. The dies 206(1), 206(2) are disposed horizontally adjacent to each other in the X-axis direction in this example with a die separation area 212 of distance D₁ of the area between the dies 206(1), 206(2). In this example, the dies 206(1), 206(2) are included in a die module 214. The first and second dies 206(1), 206(1) are disposed above the package substrate 208 in a vertical direction in the Z-axis direction in this example, orthogonal to the horizontal direction in the X-axis direction. The die module 214 includes the dies 206(1), 206(2) and an overmold compound 216 (e.g., an epoxy) formed around the dies 206(1), 206(2) and in the die separation area 212. For example, as discussed in more detail below, the die module 214 can include a reconstituted wafer 218 that was fabricated according to a fan-out wafer level packaging (FOWLP) process. Providing the die module 214 as a reconstituted wafer 218 can allow good die placement control so that the dies 206(1), 206(2) can be placed closer together to further reduce the width of the die separation area 212 in the horizontal, X-axis direction to reduce package size. A dielectric layer 220 is disposed on top of the die module 214. A packaging compound 222, such as a molding compound, is disposed on the dielectric layer 220 as part of the split die IC package 200.

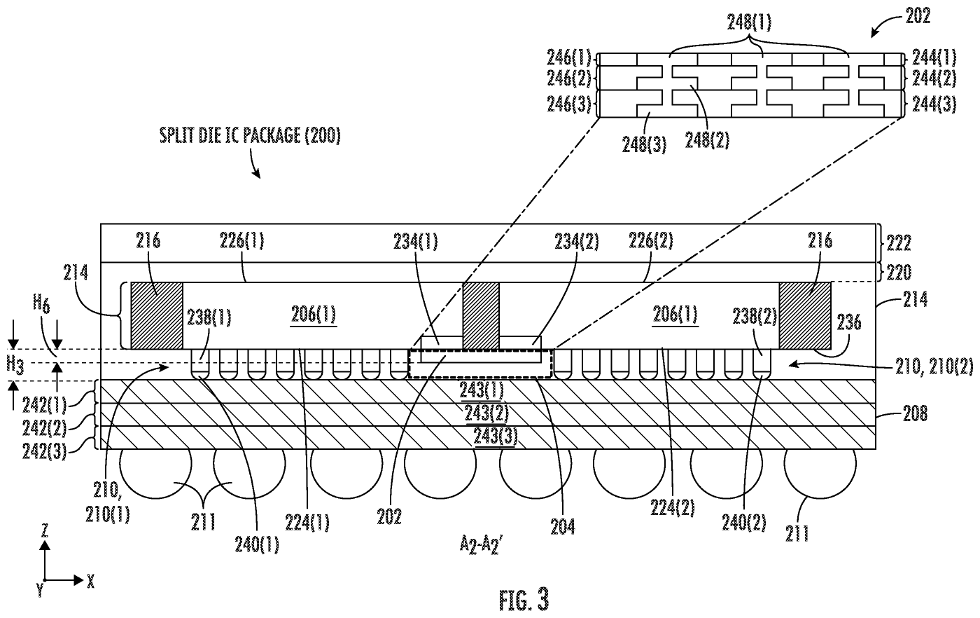

As shown in FIG. 2B, a first and second plurality of die interconnects 210(1), 210(2) are coupled to the package substrate 208 and the respective first and second dies 206(1), 206(2). The first and second dies 206(1), 206(2) have respective active sides 224(1), 224(2) and back sides 226(1), 226(2). The die interconnects 210(1) are coupled to the active side 224(1) of the die 206(1) and the package substrate 208. The die interconnects 210(2) are coupled to the active side 224(2) of the die 206(2) and the package substrate 208. The first and second plurality of die interconnects 210(1), 210(2) coupled to the package substrate 208 and the respective first and second dies 206(1), 206(2) create the die standoff area 228 between the first and second dies 206(1), 206(2) and the package substrate 208. The die-substrate standoff cavity 204 is formed in the die standoff area 228 between the die interconnects 210(1), 210(2). The D2D interconnect structure 202 is disposed in the die-substrate standoff cavity 204. As discussed in more detail below with regard to FIG. 3, the D2D interconnect structure 202 includes D2D interconnects 232 coupled to the first die 206(1) and the second die 206(2) to provide D2D connections between the dies 206(1), 206(2). In this example, die 206(1) includes D2D interface circuitry 234(1) that provides a D2D communication interface to die 206(2). The D2D interface circuitry 234(1) is horizontally adjacent to the die separation area 212. Also in this example, die 206(2) includes D2D interface circuitry 234(2) that provides a D2D communication interface to die 206(1). The D2D interface circuitry 234(2) is also horizontally adjacent to the die separation area 212. The D2D interface circuitries 234(1), 234(2) are disposed above and in contact with the D2D interconnect structure 202 to be coupled to D2D interconnects 232 therein to couple the D2D interface circuitries 234(1), 234(2) together for D2D communications.

In this example, the D2D interconnect structure 202 and its D2D interconnects 232 are not disposed in the package substrate 208. The D2D interconnects 232 are not coupled to the package substrate 208 including metal interconnects (e.g., metal lines, metal traces, vertical interconnect accesses (vias), pads) in its metallization layers in this example to avoid consuming area in the package substrate 208 for D2D connections provided by the D2D interconnect structure 202.

FIG. 3 is another cross-sectional side view of the split die IC package 200 in FIGS. 2A and 2B to illustrate additional exemplary detail including the D2D interconnect structure 202 in the die-substrate standoff cavity 204. The cross-sectional side view of the split die IC package 200 in FIG. 3 is also along the A₂-A₂′ line of the split IC die package 200 in FIG. 2A.

As shown in FIG. 3, in this example, die module 214 has an active side 236 that is adjacent to the package substrate 208. The first and second active sides 224(1), 224(2) of the first and second dies 206(1), 206(2) are disposed on the active side 236 of the package substrate 208 so that connections can be made between the first and second dies 206(1), 206(2) and the package substrate 208 through the respective first and second die interconnects 210(1), 210(2). The first die interconnects 210(1) are coupled to the first active side 224(1) of the first die 206(1). The second die interconnects 210(2) are coupled to the second active side 224(2) of the second die 206(2). The first and second die interconnects 210(1), 210(2) each include a metal pillar 238(1), 238(2) (e.g. copper pillars) coupled to a die pad on the respective first and second active sides 224(1), 224(2) of the respective first and second dies 206(1), 206(2). Interconnect bumps 240(1), 240(2) (e.g., solder bumps or caps) are disposed on the metal pillars 238(1), 238(2) to form an electrical connection to the package substrate 208. The package substrate 208 includes one or more metallization layers 242(1)-242(3) for making electrical connections between the dies 206(1), 206(2), through the die interconnects 210(1), 210(2). The die interconnects 210(1), 210(2) are coupled to one or more metal interconnects 243(1)-243(3) (e.g., metal lines, metal traces, vertical interconnect accesses (vias), pads) in the metallization layers 242(1)-242(3) of the package substrate 208. The height H₃ of the die interconnects 210(1), 210(1) defines the height H₃ of the die-substrate standoff cavity 204 in the vertical direction in the Z-axis. The D2D interconnect structure 202 has a height H₆ in the vertical direction in the Z-axis that is less than the height H₃ of the die-substrate standoff cavity 204 so that the D2D interconnect structure 202 can be disposed in the die-substrate standoff cavity 204 without consuming area in the package substrate 208, if desired. The overmold compound 216 is disposed adjacent to the first and second back sides 226(1), 226(2) of the first and second dies 206(1), 206(2).

As an example, as discussed in more detail below, the die module 214 can be a reconstituted die module that is fabricated according to a FOWLP process. This may allow the D2D interconnect structure 202 to be built onto the die module 214 in one or more metallization layers more easily as part of the fabrication process of the split die IC package 200. For example, the D2D interconnect structure 202 can include one or more metallization layers 244(1)-244(3) that are each RDLs 246(1)-246(3) that each include metal interconnects 248(1)-248(3) (e.g., metal lines, metal traces, vertical interconnect accesses (vias), pads). For example, it may be easier to achieve a smaller L/S ratio in the metal interconnects 248(1)-248(3) in the metallization layers 244(1)-244(3) if the metallization layers 244(1)-244(3) are RDLs 246(1)-246(3). For example, the L/S ratio of the metal interconnects 248(1)-248(3) be 2/2 or 1/1. As an example, the height H₃ of the die interconnects 210(1), 210(2) may be between 30-40 micrometers (μm), the height of each of the RDLs 246(1)-246(3) may be less than or equal to 7 μm, and the metal interconnects 248(1)-248(3) may have a L/S ratio of 2/2 or less.

The first die 206(1), and more particularly the D2D interface circuitry 234(1), can be coupled to a metal interconnect 248(1) in a first RDL 246(1) to be coupled to the D2D interconnect structure 202. The second die 206(1), and more particularly the D2D interface circuitry 234(2), can also be coupled to a metal interconnect 248(1) in the first RDL 246(1) to be coupled to the D2D interconnect structure 202. In this manner, the D2D interface circuitries 234(1), 234(2) can be coupled together for D2D communications through the D2D interconnect structure 202. To make the connectivity more spatially efficient, the D2D interface circuitries 234(1), 234(2) in the first and second dies 206(1), 206(2) may be located to be disposed above and/or overlap or partially overlap the die-substrate standoff cavity 204 in a vertical direction in the Z-axis to make connections to the D2D interconnect structure 202.

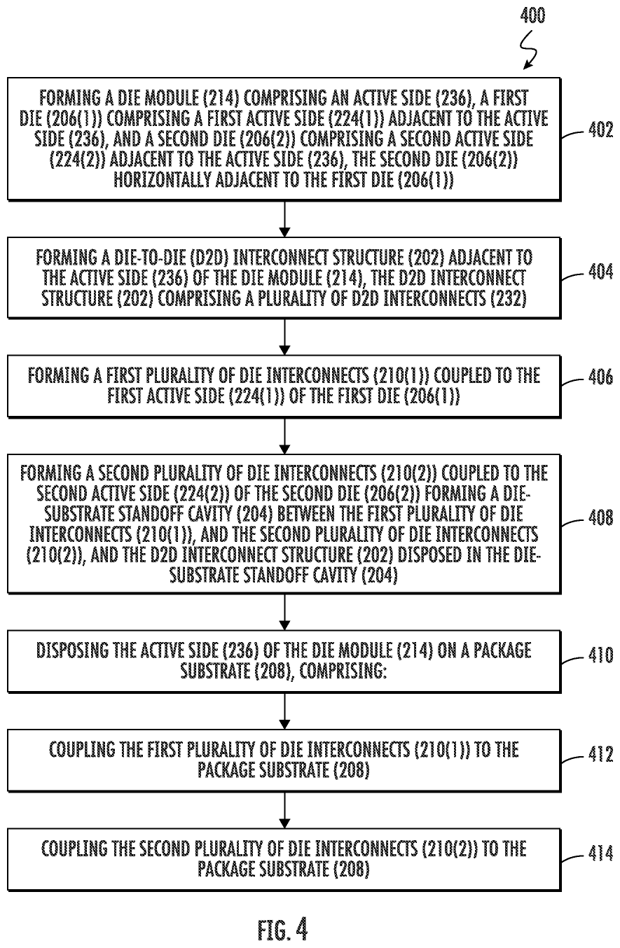

FIG. 4 is a flowchart illustrating an exemplary process 400 for fabricating a split die IC package employing a D2D interconnect structure in a die-substrate standoff cavity to provide D2D connections, including, but not limited to, the exemplary split die IC package 200 in FIGS. 2A-3. The exemplary process 400 in FIG. 4 is described with regard to the split die IC package 200 in FIGS. 2A-3 as an example, but this process is also applicable to other split die IC packages that employ a D2D interconnect structure in a die-substrate standoff cavity to provide D2D connections.

In this regard, with reference to FIG. 4, a first fabrication step includes forming a die module 214 comprising an active side 236, a first die 206(1) comprising a first active side 224(1) adjacent to the active side 236, and a second die 206(2) comprising a second active side 224(1) adjacent to the active side 236, the second die 206(2) horizontally adjacent to the first die 206(1) (block 402 in FIG. 4). A next fabrication step in the process 400 includes forming a D2D interconnect structure 202 adjacent to the active side 236 of the die module 214, the D2D interconnect structure 202 comprising a plurality of D2D interconnects 232 (block 404 in FIG. 4). A next fabrication step in the process 400 includes forming a first plurality of die interconnects 210(1) coupled to the first active side 224(1) of the first die 206(1) (block 406 in FIG. 4). A next fabrication step in the process 400 includes forming a second plurality of die interconnects 210(2) coupled to the second active side 224(2) of the second die 206(2) forming a die-substrate standoff cavity 204 between the first plurality of die interconnects 210(1) and the second plurality of die interconnects 210(2), wherein the D2D interconnect structure 202 is disposed in the die-substrate standoff cavity 204 (block 408 in FIG. 4). A next fabrication step in the process 400 includes disposing the active side 236 of the die module 214 on a package substrate 208 (block 410 in FIG. 4). Disposing the active side 236 of the die module 214 on the package substrate 208 includes coupling the first plurality of die interconnects 210(1) to the package substrate 208 (block 412 in FIG. 4), and coupling the second plurality of die interconnects 210(2) to the package substrate 208 (block 414 in FIG. 4).

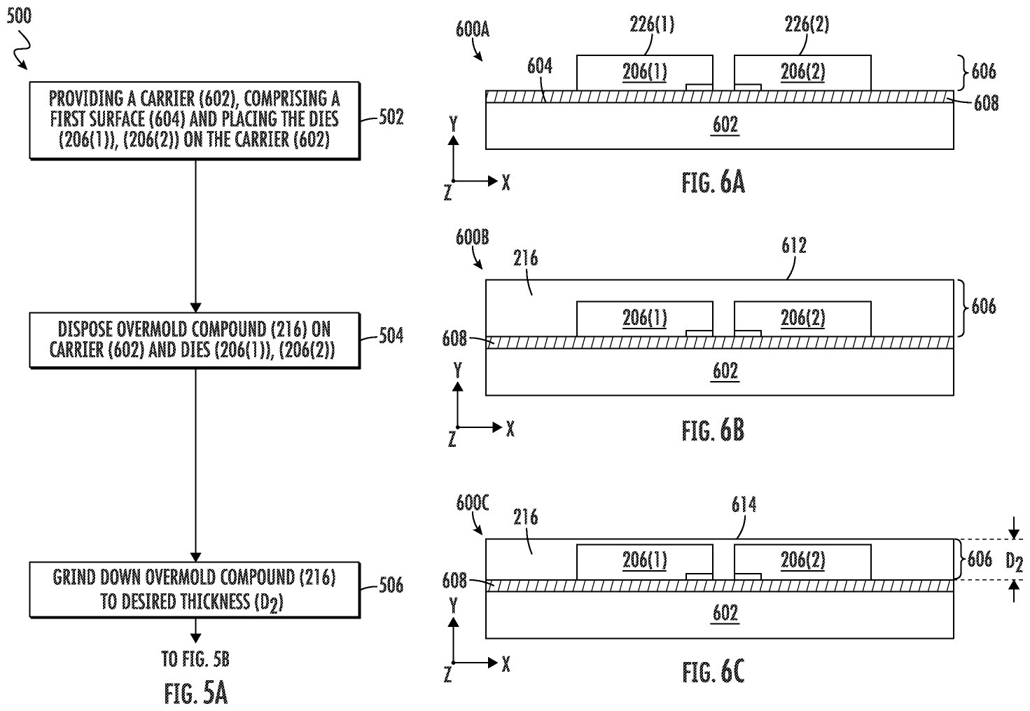

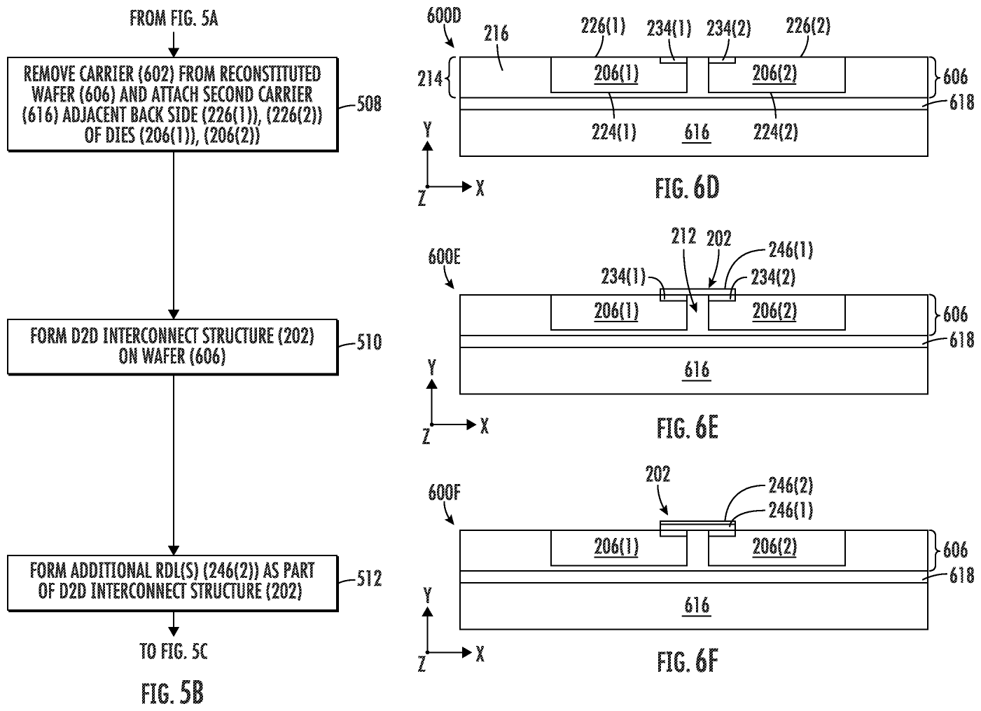

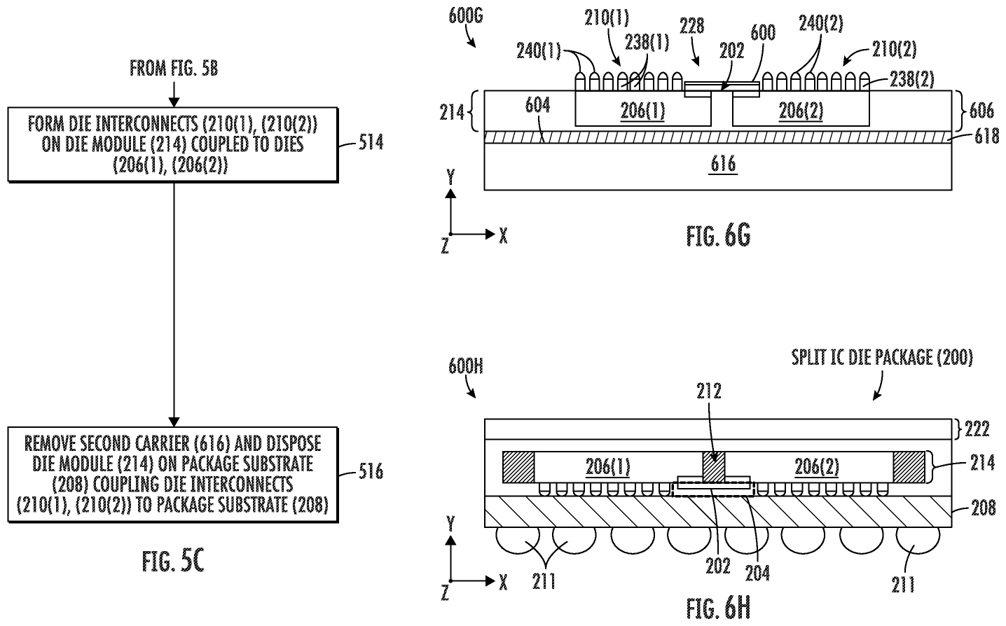

FIGS. 5A-5C are a flowchart illustrating another exemplary process 500 for fabricating a split die IC package employing a D2D interconnect structure in a die-substrate standoff cavity to provide D2D connections including, but not limited to, the exemplary split die IC package in FIGS. 2A-3. FIGS. 6A-6H illustrate exemplary fabrication stages 600A-600H for a split die IC package employing a D2D interconnect structure in a die-substrate standoff cavity to provide D2D connections according to the exemplary fabrication process 500 in FIGS. 5A-5C. The fabrication process 500 in FIGS. 5A-5C will now be discussed in conjunction with the exemplary fabrication stages 600A-600H in FIGS. 6A-6H.

In this regard, with reference to the process 500 in FIG. 5A, a first step in the fabrication of the split die IC package 200 may be to fabricate the die module 214 as a reconstituted die module. As shown in the fabrication stage 600A in FIG. 6A, this involves providing a carrier 602 comprising a first surface 604 for forming reconstituted die module 214 as a reconstituted wafer 606 and placing (and positioning) the dies 206(1), 206(2) horizontally adjacent to each other in the X-axis direction on the carrier 602 (block 502 in FIG. 5A). The carrier 602 provides a structure that allows positioning and manipulation of the dies 206(1), 206(2) to form the die module 214. As discussed below, providing the die module 214 as a reconstituted wafer 606 can provide for the ability to form the D2D interconnect structure 202 on the die module 214 adjacent to the active sides 224(1), 224(2) of the dies 206(1), 206(2) before the die module 214 is disposed on the package substrate 208. For example, the D2D interconnect structure 202 may be preferably formed as one or more RDLs, such as RDLs 246(1)-246(3) in FIG. 3, on the die module 214. A temporary adhesive film 608 may be placed on the first surface 604 of the carrier 602 before the dies 206(1), 206(2) are disposed on the adhesive film 608 to provide an adhesive for the dies 206(1), 206(2) to be securely attached to the carrier 602.

As shown in a next fabrication stage 600B in FIG. 6B, a next step in forming the die module 214 as the reconstituted wafer 606 is to dispose the overmold compound 216 (e.g., an epoxy mold) on the first surface 604 of the carrier and on and over the first and second back sides 226(1), 226(2) of the respective first and second dies 206(1), 206(2) to secure the dies 206(1), 206(2) and to provide dielectric isolation to the dies 206(1), 206(2) (block 504 in FIG. 5A). As shown in a next fabrication stage 600C in FIG. 6C, a next step in forming the die module 214 as the reconstituted wafer 606 is to grind down a top surface 612 (FIG. 6B) of the overmold compound 216 towards the back sides 226(1), 226(2) of the dies 206(1), 206(2) to a reduced surface 614 to a desired thickness D2 (block 506 in FIG. 5A). Alternatively, the overmold compound 216 could be ground down to the back sides 226(1), 226(2) of the dies 206(1), 206(2).

As shown in a next fabrication stage 600D in FIG. 6D, a next step in is to remove the carrier 602 from the reconstituted wafer 606 and attach a second carrier 616 to the reconstituted wafer 606 adjacent to the back sides 226(1), 226(2) of the dies 206(1), 206(2) (block 508 in FIG. 5B). The carrier 602 is removed to expose the active sides 224(1), 224(2) of the dies 206(1), 206(2), and more particularly the D2D interface circuitry 234(1), 234(2) to prepare the D2D interconnect structure 202 to be formed on the reconstituted wafer 606 and coupled to the active sides 224(1), 224(2) and the D2D interface circuitry 234(1), 234(2) of the dies 206(1), 206(2). An adhesive layer 618 may be disposed first on the second carrier 616 before the reconstituted wafer 606 is attached to the second carrier 616 to secure the reconstituted wafer 606 to the second carrier 616 as shown in FIG. 6D.

Then, as shown in a next fabrication stage 600E in FIG. 6E, a next step is forming the D2D interconnect structure 202 on a portion of the first active side 224(1) of the first die 206(1) and a portion of the second active side 224(2) of the second die 206(2) in what will be formed as a die-substrate standoff cavity 204 in a later fabrication stage (block 510 in FIG. 5B). The D2D interconnect structure 202 is disposed vertically adjacent in the Z-axis direction to the horizontal die separation area 212 between the first die 206(1) and the second die 206(2). The fabrication stage 600E shows a first RDL 246(1) being formed on the reconstituted wafer 606 coupled to the D2D interface circuitry 234(1), 234(2) of the dies 206(1), 206(2) as part of the D2D interconnect structure 202. As shown in a next fabrication stage 600F in FIG. 6F, an additional RDL(s) 246(2) can be formed on the first RDL 246(1) to form part of the D2D interconnect structure 202 (block 512 in FIG. 5B). Forming the RDLs 246(1), 246(2) in this example can include a conventional process for forming RDLs, including providing a coating layer on the die module 214, removing portions of the coating with a patterning process to expose the die pads for the D2D interface circuitry 234(1), 234(2), depositing a seed layer, and performing a lithography process to form the metal interconnects in the RDLs 246(1), 246(2). A solder resist layer 620 can also be formed on the D2D interconnect structure 202 when fully built to protect the RDLs 246(1), 246(2) from solder exposure when forming the die interconnects 210(1), 210(2)

As shown in a next fabrication stage 600G in FIG. 6G, a next step is to form the die interconnects 210(1), 210(2) on the reconstituted wafter 606 and in contact with the dies 206(1), 206(2) (block 514 in FIG. 5C). This involves forming metal pillars 238(1), 238(2) and interconnect bumps 240(1), 240(2). As discussed above, this will create the die standoff area 228 when the die module 214 is formed from the reconstituted wafer 606 in the area between the die interconnects 210(1), 210(2). The cavity formed by the die standoff area 228 between the die module 214 and the package substrate 208 (FIGS. 2B and 3) will create the die-substrate standoff cavity 204 that retains room and space for the D2D interconnect structure 202 to be present in the final split die IC package 200 without having to consume area in the package substrate 208. Die singulation may be used to separate die modules 214 if multiple die modules 214 are formed as part of the reconstituted wafer 606. As shown in a next fabrication stage 600H in FIG. 6H, a next step is to remove the second carrier 616 and dispose the active side 236 of the die module 214 on a package substrate 208 coupling the die interconnects 210(1), 210(2) to the package substrate 208 to form the split die IC package 200 (block 516 in FIG. 5C).

A split die IC package(s) employing a D2D interconnect structure in a die-substrate standoff cavity to provide D2D connections including, but not limited to, the exemplary split die IC package in FIGS. 2A-3, and according to the exemplary fabrication processes in FIGS. 4-6H may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

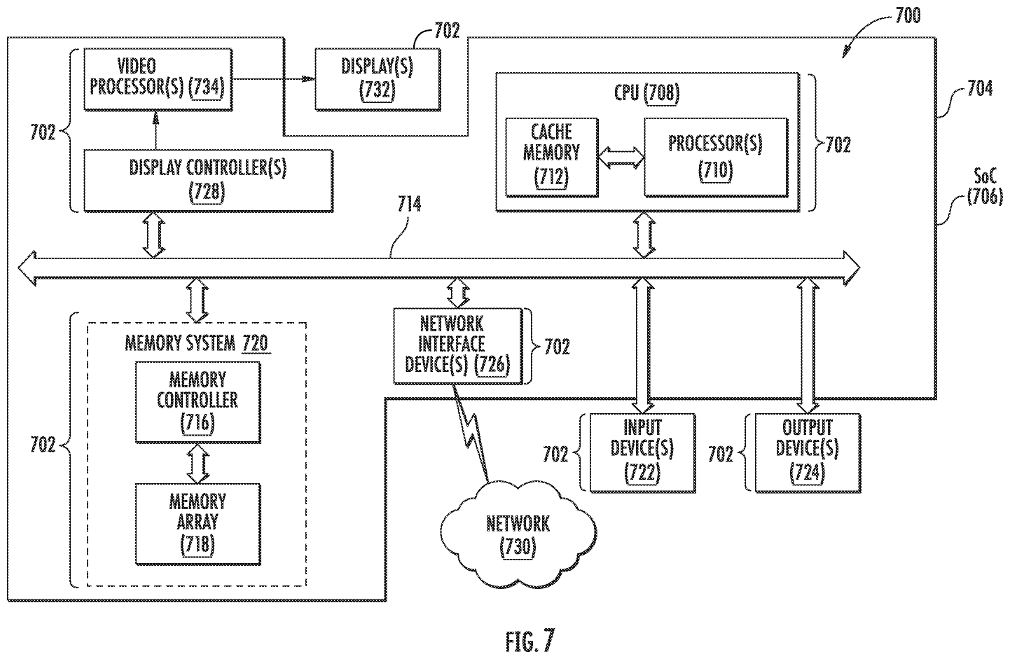

In this regard, FIG. 7 illustrates an example of a processor-based system 700. The components of the processor-based system 700 are ICs 702. Some or all of the ICs 702 in the processor-based system 700 can be provided in a split die IC package(s) 704 that employs a D2D interconnect structure in a die-substrate standoff cavity (i.e., cavity) to provide D2D connections including, but not limited to, the exemplary split die IC package in FIGS. 2A-3, and according to the exemplary fabrication processes in FIGS. 4-6H, and according to any aspects disclosed herein. In this example, the processor-based system 700 may be formed as a split die IC package 704 and as a system-on-a-chip (SoC) 706. The processor-based system 700 includes a CPU 708 that includes one or more processors 710, which may also be referred to as CPU cores or processor cores. The CPU 708 may have cache memory 712 coupled to the CPU 708 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716 as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. Each of the memory system 720, the one or more input devices 722, the one or more output devices 724, the one or more network interface devices 726, and the one or more display controllers 728 can be provided in the same or different IC packages. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processors 734, which process the information to be displayed into a format suitable for the display(s) 732. The display controller(s) 728 and video processor(s) 734 can be included as split die IC package 704 and the same or different IC packages, and in the same or different IC packages containing the CPU 708 as an example. The display(s) 732 can include any type of display, including, but not limited to, a cathode ray tube (CRT), a liquid crystal display (LCD), a plasma display, a light emitting diode (LED) display, etc.

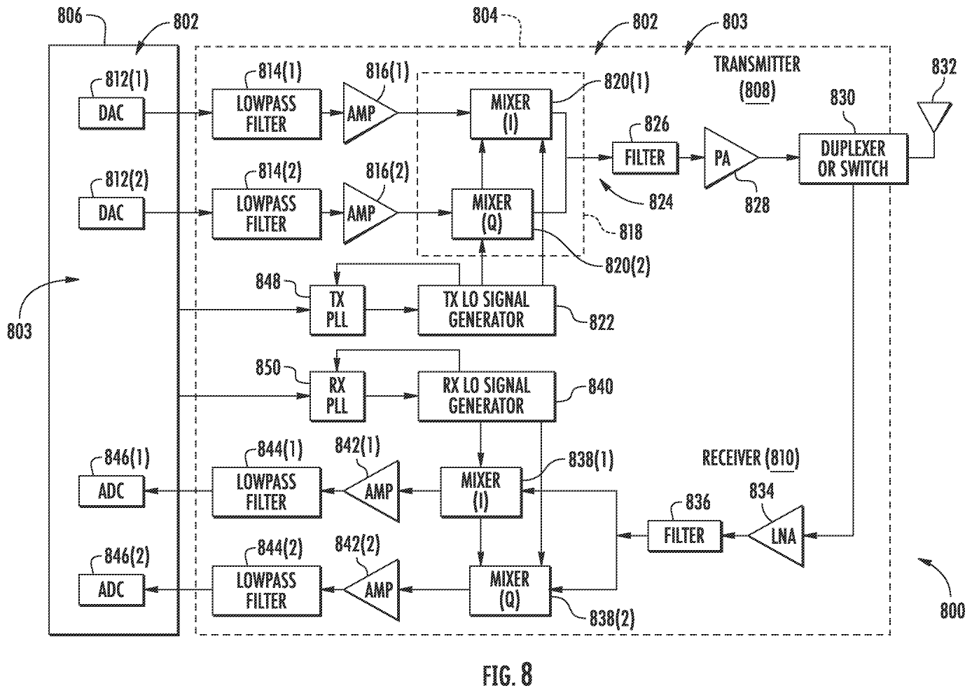

FIG. 8 illustrates an exemplary wireless communications device 800 that includes radio frequency (RF) components formed from one or more ICs 802, wherein any of the ICs 802 can include a split die IC package(s) 803 that employs a D2D interconnect structure in a die-substrate standoff cavity (i.e., cavity) to provide D2D connections including, but not limited to, the exemplary split die IC package in FIGS. 2A-3, and according to the exemplary fabrication processes in FIGS. 4-6H, and according to any aspects disclosed herein. The wireless communications device 800 may include or be provided in any of the above-referenced devices, as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RFICs, mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs)816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency upconversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered aspects/clauses:

1. An integrated circuit (IC) package, comprising:
a package substrate;
a first die;
a second die;
a first plurality of die interconnects coupled to the package substrate and the first die creating a die standoff area between the first die and the package substrate;
a second plurality of die interconnects disposed in the die standoff area and coupled to the package substrate and the second die;
a cavity formed in the die standoff area between the first plurality of die interconnects and the second plurality of die interconnects; and a die-to-die (D2D) interconnect structure disposed in the cavity, the D2D interconnect structure comprising a plurality of D2D interconnects coupled to the first die and the second die.
   2. The IC package of clause 1, wherein the plurality of D2D interconnects are not coupled to the package substrate.
   3. The IC package of any of clauses 1 and 2, wherein;
the second die is horizontally adjacent to the first die in a horizontal direction;
a first active side of the first die is disposed adjacent to the package substrate in a vertical direction orthogonal to the horizontal direction; and
a second active side of the second die is disposed adjacent to the package substrate in the vertical direction.
   4. The IC package of clause 3, wherein a height of the D2D interconnect structure in the vertical direction is less than a height of the die-substrate standoff cavity in the vertical direction.
   5. The IC package of any of clauses 3 and 4, wherein:
the second die is horizontally adjacent to the first die by a spaced distance forming a horizontal die separation area between the first die and the second die; and
the die-substrate standoff cavity is partially disposed adjacent to the horizontal die separation area in the vertical direction.
   6. The IC package of any of clauses 3-5, wherein a height of the first plurality of die interconnects and the second plurality of die interconnects in the vertical direction defines a height of the cavity in the vertical direction.
   7. The IC package of any of clauses 3-6, wherein the D2D interconnect structure comprises a redistribution layer (RDL) comprising at least one metal interconnect coupled to the first die and the second die.
   8. The IC package of clause 7, wherein the RDL comprises a plurality of metal interconnects having a line space (L/S) ratio of 2/2 or smaller.
   9. The IC package of any of clauses 7 and 8, wherein;
a height of the first plurality of die interconnects and the second plurality of die interconnects is between 30-40 micrometers (μm)
a height of the RDL is less than or equal to 7 μm; and
the RDL comprises a plurality of metal interconnects having a line space (L/S) ratio of 2/2 or smaller.
   10. The IC package of any of clauses 1-9, wherein:
the first die comprises a first active side and a first back side;
the second die comprises a second active side and a second back side;
the first plurality of die interconnects couples the first active side of the first die to the package substrate; and
the second plurality of die interconnects couples the second active side of the second die to the package substrate.
   11. The IC package of any of clauses 1-10, further comprising a reconstituted die module comprising:
an active side adjacent to the package substrate;
the first die comprising a first active side on the active side and a first back side;
the second die comprising a second active side on the active side and a second back side; and
a mold compound disposed adjacent to the first back side of the first die and the second back side of the second die.
   12. The IC package of any of clauses 1-11, wherein:
the second die is horizontally adjacent to the first die by a spaced distance forming a horizontal die separation area between the first die and the second die;
the first die comprises a first D2D interface circuitry horizontally adjacent to the horizontal die separation area;
the second die comprises a second D2D interface circuitry horizontally adjacent to the horizontal die separation area;
the first D2D interface circuitry is coupled to the D2D interconnect structure;
the second D2D interface circuitry is coupled to the D2D interconnect structure; and
the D2D interconnect structure couples the first D2D interface circuitry to the second D2D interface circuitry.
   13. The IC package of clause 12, wherein:
the D2D interconnect structure comprises one or more metallization layers each comprising one or more metal interconnects;
the first die is coupled to one or more metal interconnects in the one or more metallization layers of the D2D interconnect structure; and
the second die is coupled to one or more metal interconnects in the one or more metallization layers of the D2D interconnect structure.
   14. The IC package of clause 13, wherein:
the one or more metallization layers comprise one or more redistribution layers (RDLs) each comprising one or more metal interconnects;
the first die is coupled to one or more metal interconnects in the one or more RDLs of the D2D interconnect structure; and
the second die is coupled to one or more metal interconnects in the one or more RDLs of the D2D interconnect structure.
   15. The IC package of clause of any of clauses 12-14, wherein:
the second die is horizontally adjacent to the first die in a horizontal direction;
the first D2D interface circuitry is disposed above the cavity in a vertical direction orthogonal to the horizontal direction; and
the second D2D interface circuitry is disposed above the cavity in the vertical direction.
   16. The IC package of any of clauses 1-15, wherein:
the first plurality of die interconnects comprises a plurality of metal pillars; and
the second plurality of die interconnects comprises a plurality of metal pillars.
   17. The IC package of any of clauses 1-16, wherein the package substrate comprises one or more metallization layers each comprising a plurality of metal interconnects;
the first plurality of die interconnects coupled to one or more metal interconnects among the plurality of metal interconnects in the package substrate; and
the second plurality of die interconnects coupled to one or more metal interconnects among the plurality of metal interconnects in the package substrate.
   18. The IC package of any of clauses 1-17 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
   19. A method of fabricating an integrated circuit (IC) package, comprising:
forming a die module comprising an active side, a first die comprising a first active side adjacent the active side, and a second die comprising a second active side adjacent to the active side, the second die horizontally adjacent to the first die;
forming a die-to-die (D2D) interconnect structure adjacent to the active side of the die module, the D2D interconnect structure comprising a plurality of D2D interconnects;
forming a first plurality of die interconnects coupled the first active side of the first die; and
forming a second plurality of die interconnects coupled to the second active side of the second die forming a cavity between the first plurality of die interconnects and the second plurality of die interconnects, and the D2D interconnect structure disposed in the cavity;
disposing the active side of the die module on a package substrate, comprising:
   coupling the first plurality of die interconnects to the package substrate; and
   coupling the second plurality of die interconnects to the package substrate.
      20. The method of clause 19, further comprising not coupling the plurality of D2D interconnects to the package substrate.
      21. The method of any of clauses 19 and 20, wherein forming the D2D interconnect structure further comprises:
coupling a first D2D interface circuitry in the first die horizontally to the D2D interconnect structure; and
coupling a second D2D interface circuitry in the second die to the D2D interconnect structure to couple the second D2D interface circuitry to the first D2D interface circuitry.
   22. The method of any of clauses 19-21, wherein forming the die module comprises: providing a carrier comprising a first surface;
placing the first die on the first surface of the carrier; and
placing the second die on the first surface of the carrier and horizontally adjacent to the first die.
   23. The method of clause 22, wherein forming the die module further comprises: applying an adhesive film to the first surface of the carrier; and wherein:
placing the first die on the first surface of the carrier comprises placing the first die on the adhesive film; and
placing the second die on the first surface of the carrier comprises placing the second die on the adhesive film horizontally adjacent to the first die.
   24. The method of any of clauses 22 and 23, further comprising disposing an overmolding compound on the first surface of the carrier and on a first back side of the first die and a second back side of the second die.
   25. The method of clause 24, further comprising grinding down a top surface of the overmolding compound towards the first back side of the first die and the second back side of the second die.
   26. The method of any of clauses 24 and 25, further comprising:
removing the carrier from the die module; and
attaching a second carrier to the die module adjacent to the first back side of the first die and the second back side of the second die.
   27. The method of clause 26, further comprising forming the D2D interconnect structure on a portion of the first active side of the first die and a portion of the second active side of the second die in the cavity.
   28. The method of clause 27, wherein the D2D interconnect structure is disposed vertically adjacent to a horizontal die separation area between the first die and the second die.
   29. The method of any of clauses 27 and 28, wherein forming the D2D interconnect structure comprises:
forming a first redistribution layer (RDL) on the first active side of the first die and the second active side of the second die in the cavity; and
forming one or more additional RDLs on the first RDL.
   30. The method of any of clauses 27-29, further comprising removing the second carrier from the die module.
   31. The method of any of clauses 27-30, further comprising coupling the first plurality of die interconnects and the second plurality of die interconnects to the package substrate.

1. An integrated circuit (IC) package, comprising:
a package substrate;
a first die;
a second die;
a first plurality of die interconnects coupled to the package substrate and the first die creating a die standoff area between the first die and the package substrate;
a second plurality of die interconnects disposed in the die standoff area and coupled to the package substrate and the second die;
a cavity formed in the die standoff area between the first plurality of die interconnects and the second plurality of die interconnects; and
a die-to-die (D2D) interconnect structure disposed in the cavity, the D2D interconnect structure comprising a plurality of D2D interconnects coupled to the first die and the second die.

2. The IC package of claim 1, wherein the plurality of D2D interconnects are not coupled to the package substrate.

3. The IC package of claim 1, wherein:
the second die is horizontally adjacent to the first die in a horizontal direction;
a first active side of the first die is disposed adjacent to the package substrate in a vertical direction orthogonal to the horizontal direction; and
a second active side of the second die is disposed adjacent to the package substrate in the vertical direction.

4. The IC package of claim 3, wherein a height of the D2D interconnect structure in the vertical direction is less than a height of the cavity in the vertical direction.

5. The IC package of claim 3, wherein:
the second die is horizontally adjacent to the first die by a spaced distance forming a horizontal die separation area between the first die and the second die; and
the cavity is partially disposed adjacent to the horizontal die separation area in the vertical direction.

6. The IC package of claim 3, wherein a height of the first plurality of die interconnects and the second plurality of die interconnects in the vertical direction defines a height of the cavity in the vertical direction.

7. The IC package of claim 1, wherein the D2D interconnect structure comprises a redistribution layer (RDL) comprising at least one metal interconnect coupled to the first die and the second die.

8. The IC package of claim 7, wherein the RDL comprises a plurality of metal interconnects having a line space (L/S) ratio of 2/2 or smaller.

9. The IC package of claim 7, wherein:
a height of the first plurality of die interconnects and the second plurality of die interconnects is between 30-40 micrometers (μm)
a height of the RDL is less than or equal to 7 μm; and
the RDL comprises a plurality of metal interconnects having a line space (L/S) ratio of 2/2 or smaller.

10. The IC package of claim 1, wherein:
the first die comprises a first active side and a first back side;
the second die comprises a second active side and a second back side;
the first plurality of die interconnects couples the first active side of the first die to the package substrate; and
the second plurality of die interconnects couples the second active side of the second die to the package substrate.

11. The IC package of claim 1, further comprising a reconstituted die module comprising:
an active side adjacent to the package substrate;
the first die comprising a first active side on the active side and a first back side;
the second die comprising a second active side on the active side and a second back side; and
a mold compound disposed adjacent to the first back side of the first die and the second back side of the second die.

12. The IC package of claim 1, wherein:
the second die is horizontally adjacent to the first die by a spaced distance forming a horizontal die separation area between the first die and the second die;
the first die comprises a first D2D interface circuitry horizontally adjacent to the horizontal die separation area;
the second die comprises a second D2D interface circuitry horizontally adjacent to the horizontal die separation area;
the first D2D interface circuitry is coupled to the D2D interconnect structure;
the second D2D interface circuitry is coupled to the D2D interconnect structure; and
the D2D interconnect structure couples the first D2D interface circuitry to the second D2D interface circuitry.

13. The IC package of claim 12, wherein:
the D2D interconnect structure comprises one or more metallization layers each comprising one or more metal interconnects;
the first die is coupled to one or more metal interconnects in the one or more metallization layers of the D2D interconnect structure; and
the second die is coupled to one or more metal interconnects in the one or more metallization layers of the D2D interconnect structure.

14. The IC package of claim 13, wherein:
the one or more metallization layers comprise one or more redistribution layers (RDLs) each comprising one or more metal interconnects;
the first die is coupled to one or more metal interconnects in the one or more RDLs of the D2D interconnect structure; and
the second die is coupled to one or more metal interconnects in the one or more RDLs of the D2D interconnect structure.

15. The IC package of claim 12, wherein:
the second die is horizontally adjacent to the first die in a horizontal direction;
the first D2D interface circuitry is disposed above the cavity in a vertical direction orthogonal to the horizontal direction; and
the second D2D interface circuitry is disposed above the cavity in the vertical direction.

16. The IC package of claim 1, wherein:
the first plurality of die interconnects comprises a plurality of metal pillars; and
the second plurality of die interconnects comprises a plurality of metal pillars.

17. The IC package of claim 1, wherein the package substrate comprises one or more metallization layers each comprising a plurality of metal interconnects;
the first plurality of die interconnects coupled to one or more metal interconnects among the plurality of metal interconnects in the package substrate; and
the second plurality of die interconnects coupled to one or more metal interconnects among the plurality of metal interconnects in the package substrate.

18. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

19. The method of claim 32, further comprising:
forming a die module comprising an active side, the first die comprising a first active side adjacent the active side, and the second die comprising a second active side adjacent to the active side, the second die horizontally adjacent to the first die;
wherein:
disposing the D2D interconnect structure further comprises disposing the D2D interconnect structure adjacent to the active side of the die module;
coupling the first plurality of die interconnects to the first die comprises coupling the first plurality of die interconnects the first active side of the first die; and
coupling the second plurality of die interconnects to the second die comprises coupling the second plurality of die interconnects to the second active side of the second die forming the cavity between the first plurality of die interconnects and the second plurality of die interconnects; and
further comprising:
disposing the active side of the die module on the package substrate, comprising:
coupling the first plurality of die interconnects to the package substrate; and
coupling the second plurality of die interconnects to the package substrate.

20. The method of claim 32, further comprising not coupling the plurality of D2D interconnects to the package substrate.

21. The method of claim 32, wherein forming the D2D interconnect structure further comprises:
coupling a first D2D interface circuitry in the first die horizontally to the D2D interconnect structure; and
coupling a second D2D interface circuitry in the second die to the D2D interconnect structure to couple the second D2D interface circuitry to the first D2D interface circuitry.

22. The method of claim 19, wherein forming the die module comprises:
providing a carrier comprising a first surface;
placing the first die on the first surface of the carrier; and
placing the second die on the first surface of the carrier and horizontally adjacent to the first die.

23. The method of claim 22, wherein forming the die module further comprises:
applying an adhesive film to the first surface of the carrier; and
wherein:
placing the first die on the first surface of the carrier comprises placing the first die on the adhesive film; and
placing the second die on the first surface of the carrier comprises placing the second die on the adhesive film horizontally adjacent to the first die.

24. The method of claim 22, further comprising disposing an overmolding compound on the first surface of the carrier and on a first back side of the first die and a second back side of the second die.

25. The method of claim 24, further comprising grinding down a top surface of the overmolding compound towards the first back side of the first die and the second back side of the second die.

26. The method of claim 24, further comprising:
removing the carrier from the die module; and
attaching a second carrier to the die module adjacent to the first back side of the first die and the second back side of the second die.

27. The method of claim 26, further comprising forming the D2D interconnect structure on a portion of the first active side of the first die and a portion of the second active side of the second die in the cavity.

28. The method of claim 27, wherein the D2D interconnect structure is disposed vertically adjacent to a horizontal die separation area between the first die and the second die.

29. The method of claim 27, wherein forming the D2D interconnect structure comprises:
forming a first redistribution layer (RDL) on the first active side of the first die and the second active side of the second die in the cavity; and
forming one or more additional RDLs on the first RDL.

30. The method of claim 27, further comprising removing the second carrier from the die module.

31. The method of claim 27, further comprising coupling the first plurality of die interconnects and the second plurality of die interconnects to the package substrate.

32. A method of fabricating an integrated circuit (IC) package, comprising:
providing a package substrate;
providing a first die;
providing a second die;
coupling a first plurality of die interconnects to the package substrate and the first die creating a die standoff area between the first die and the package substrate;
disposing a second plurality of die interconnects in the die standoff area and coupled to the package substrate and the second die;
forming a cavity in the die standoff area between the first plurality of die interconnects and the second plurality of die interconnects; and
disposing a die-to-die (D2D) interconnect structure in the cavity, the D2D interconnect structure comprising a plurality of D2D interconnects coupled to the first die and the second die.
